(19) United States
(12) Patent Application Publication
(10) Pub. No.: US 2024/0418209 A1
(43) Pub. Date: Dec. 19, 2024

(54) HINGE STRUCTURE AND FOLDABLE DEVICE

(71) Applicant: VIVO MOBILE COMMUNICATION CO., LTD., Dongguan (CN)

(72) Inventors: Zhiqiang ZHAO, Dongguan (CN); Qiuyu ZHOU, Dongguan (CN); Fei DONG, Dongguan (CN); Xuyang LIU, Dongguan (CN); Renbo ZHOU, Dongguan (CN)

(73) Assignee: VIVO MOBILE COMMUNICATION CO., LTD., Dongguan (CN)

(21) Appl. No.: 18/822,339

(22) Filed: Sep. 2, 2024

Related U.S. Application Data
(63) Continuation of application No. PCT/CN2023/078800, filed on Feb. 28, 2023.

(30) Foreign Application Priority Data
Mar. 2, 2022 (CN) 202210205062.0

(51) Int. Cl. F16C 11/04; H05K 5/02

(52) U.S. Cl. CPC F16C 11/04; H05K 5/0226

(57) ABSTRACT

Disclosed are a hinge structure and a foldable device. The hinge structure includes: a first swing arm and a second swing arm; and a support structure, disposed between the first swing arm and the second swing arm. During rotation of the first swing arm and the second swing arm, two ends of the support structure are configured to contact the first swing arm and the second swing arm respectively, enabling the support structure to move between a first position and a second position. The posture of the support structure in the first position is different from the posture of the support structure in the second position.

### CROSS-REFERENCE TO RELATED APPLICATIONS

This application is a continuation of International Application No. PCT/CN2023/078800, filed Feb. 28, 2023, which claims priority to Chinese Patent Application No. 202210205062.0, filed Mar. 2, 2022. The entire contents of each of the above-referenced applications are expressly incorporated herein by reference.

### TECHNICAL FIELD

This application relates to the field of foldable device technologies, and specifically relates to a hinge structure and a foldable device.

### BACKGROUND

Currently, in the folding process of existing foldable phones, the screen usually comes into contact with the internal support structure, squeezing the screen to some extent. This can damage the screen in the event of a drop or impact. In existing technologies, to avoid this situation, a clearance space is usually set at the internal support structure. However, the screen inevitably sinks when unfolded, affecting user experience.

### SUMMARY

This application aims to provide a hinge structure and a foldable device. A movable support structure is disposed within the hinge structure and can adopt different postures as the first swing arm and the second swing arm rotate to different positions, thereby providing better support for a display screen.

To achieve the above objective, an embodiment of a first aspect of this application provides a hinge structure, including: a first swing arm and a second swing arm; and a support structure, disposed between the first swing arm and the second swing arm, where during rotation of the first swing arm and the second swing arm, two ends of the support structure are able to contact the first swing arm and the second swing arm respectively, enabling the support structure to move between a first position and a second position; where posture of the support structure in the first position is different from posture of the support structure in the second position.

The hinge structure provided according to the embodiment of this application mainly includes the first swing arm and the second swing arm for rotation, and the support structure disposed between the two swing arms to enable mutual rotation of the two swing arms. In some embodiments, during the rotation of the first swing arm and the second swing arm, the support structure moves between the first position and the second position, while the two ends of the support structure respectively contact the two swing arms, causing the posture of the support structure to change. In some embodiments, the change in the posture of the support structure refers to the change in the position of the support structure perpendicular to a plane formed by rotating shafts of the two swing arms, thereby providing certain auxiliary support uniformly in the middle of the hinge structure as the hinge structure rotates to different positions. After a display screen is disposed, this can reduce the squeezing on the screen by the support structure in the folded state, and also support the screen in the unfolded state, greatly improving the user experience during use.

The posture of the support structure includes but is not limited to position, shape, or the like, as long as it can change, dynamically supporting the screen located on one side of the hinge structure.

It should be noted that the plane formed by the rotating shafts of the first swing arm and the second swing arm is a plane passing the axis of the rotating shaft of the first swing arm and the axis of rotating shaft of the second swing arm, and a direction perpendicular to this plane is a normal direction of the plane. Generally, the first swing arm and the second swing arm are arranged parallel to each other, and this plane is the display surface after the display screen is unfolded. The change in posture in the normal direction of this plane is the change in the direction perpendicular to the display surface, which can be understood as the direction of support for the screen. As the first swing arm and the second swing arm rotate to different positions, the support structure can provide flexible support for the display screen.

An embodiment of a second aspect of this application provides a foldable device, including: a first folding body and a second folding body; and any hinge structure in the embodiments of the first aspect, where the first swing arm of the hinge structure is connected to the first folding body, and the second swing arm of the hinge structure is connected to the second folding body.

The foldable device provided according to the embodiment of this application mainly includes the first folding body, the second folding body, and the hinge structure. The first folding body and the second folding body are connected to the hinge structure, allowing the first folding body and the second folding body to rotate relative to each other, thereby changing the overall posture of the foldable device. In some embodiments, the first folding body is connected to the first swing arm of the hinge structure, and the second folding body is connected to the second swing arm of the hinge structure, so that the rotation of the first swing arm and the second swing arm can drive the first folding body and the second folding body to rotate accordingly.

Furthermore, since the foldable device includes the hinge structure according to any one of the embodiments above, it therefore has the effects of any one of the embodiments.

The foldable device includes a foldable phone, a foldable tablet, a foldable notebook, and another device with folding needs.

Additional aspects and advantages of this application will become apparent in the following description or through the practice of this application.

### BRIEF DESCRIPTION OF DRAWINGS

FIG. 1 is a schematic structural diagram a structure of a hinge structure according to an embodiment of this application;

FIG. 2 is a schematic diagram illustrating relations within a support structure according to an embodiment of this application;

FIG. 3 is a schematic structural diagram of a hinge structure according to an embodiment of this application;

FIG. 4 is a schematic structural diagram of a hinge structure according to an embodiment of this application;

FIG. 5 is a schematic structural diagram of a hinge structure according to an embodiment of this application;

FIG. 6 is a schematic structural diagram of a foldable device according to an embodiment of this application; and

FIG. 7 is a schematic structural diagram of a foldable device according to an embodiment of this application.

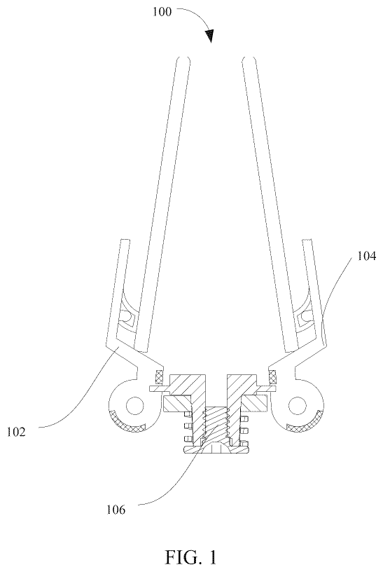

The correspondence between the reference signs and the component names in FIGS. 1 to 7 is as follows:
100: hinge structure; 102: first swing arm; 104: second swing arm; 106: support structure; 1062: floating piece; 1064: elastic piece; 108: fixing assembly; 1082: fixed plate; 1084: floating screw; 1102: first snap-fit piece; 1104: second snap-fit piece; 1106: limiting piece; 1122: first support plate; 1124: second support plate; 114: reinforcement support strip; 200: foldable device; 202: first folding body; 204: second folding body; and 206: display screen.

### DETAILED DESCRIPTION

The embodiments of this application will be described in detail below, examples of which are shown in the accompanying drawings, where the same or similar reference signs denote the same or similar elements or elements with the same or similar functions throughout. The embodiments described below with reference to the drawings are illustrative and are only used to explain this application, and should not be construed as limiting this application. Based on the embodiments in this application, all other embodiments obtained by persons of ordinary skill in the art without making creative efforts fall within the protection scope of this application.

The terms “first” and “second” preceding a feature in the specification and claims of this application can implicitly or explicitly indicate inclusion of one or more such features. In the description of this application, unless otherwise stated, “a plurality of” means at least two. In addition, “and/or” indicates in the specification and claims indicates at least one of the connected objects, and the character “/” generally indicates an “or” relationship between the contextually associated objects.

In the description of this application, it is to be noted that, unless otherwise explicitly specified or defined, the terms “mount,” “connect,” and “couple” should be broadly understood. For example, they may refer to a fixed connection, a detachable connection, or an integral connection; may refer to a mechanical connection or an electrical connection; and may refer to a direct connection, an indirect connection through an intermediary, or an internal communication of two elements. For those of ordinary skill in the art, the specific meanings of these terms in this application can be understood as appropriate to specific circumstances.

The foldable device provided in the embodiments of this application can be a foldable phone, a foldable tablet, a foldable notebook, and another device with folding needs.

A hinge structure and a foldable device provided according to embodiments of this application are described below with reference to FIGS. 1 to 7.

As shown in FIG. 1, an embodiment of this application proposes a hinge structure 100, including: a first swing arm 102 and a second swing arm 104; and a support structure 106, disposed between the first swing arm 102 and the second swing arm 104, where two ends of the support structure 106 are rotatably connected to the first swing arm 102 and the second swing arm 104 respectively. In a direction perpendicular to a plane formed by rotating shafts of the first swing arm 102 and the second swing arm 104, posture of the support structure 106 when the first swing arm 102 and the second swing arm 104 rotate to a first position is different from posture of the support structure 106 when the first swing arm 102 and the second swing arm 104 rotate to a second position.

The hinge structure 100 provided according to the embodiment of this application mainly includes the first swing arm 102 and the second swing arm 104 for rotation, and the support structure 106 disposed between the two swing arms to enable mutual rotation of the two swing arms. In some embodiments, during the rotation of the first swing arm 102 and the second swing arm 104, the support structure moves between the first position and the second position, while the two ends of the support structure respectively contact the two swing arms, causing the posture of the support structure 106 to change. In some embodiments, the change in the posture of the support structure 106 refers to the change in the position of the support structure 106 perpendicular to the plane formed by the rotating shafts of the two swing arms, thereby providing certain auxiliary support uniformly in the middle of the hinge structure 100 as the hinge structure 100 rotates to different positions. After a display screen 206 is disposed, this can reduce the squeezing of the screen by the support structure 106 in the folded state, and also support the screen in the unfolded state, greatly improving the user experience during use.

The posture of the support structure 106 includes but is not limited to position, shape, or the like, as long as it can change, dynamically supporting the screen located on one side of the hinge structure 100.

It should be noted that the plane formed by the rotating shaft of the first swing arm 102 and the rotating shaft of the second swing arm 104 is a plane passing the axis of rotating shaft of the first swing arm 102 and the axis of the rotating shaft of the second swing arm 104, and the direction perpendicular to this plane is a normal direction of the plane. Generally, the first swing arm 102 and the second swing arm 104 are arranged parallel to each other, and this plane is the display surface after the display screen 206 is unfolded. The change in posture in the normal direction of this plane is the change in the direction perpendicular to the display surface, which can be understood as the direction of support for the screen. As the first swing arm 102 and the second swing arm 104 rotate to different positions, the support structure 106 can provide flexible support for the display screen 206.

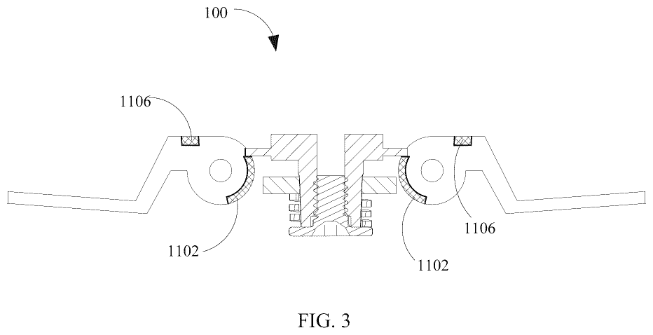

In FIG. 1, the hinge structure 100 is in a folded state, that is, the first swing arm 102 and the second swing arm 104 are in the second position, and in FIG. 3, the hinge structure 100 is in an unfolded state, that is, the first swing arm 102 and the second swing arm 104 are in the first position.

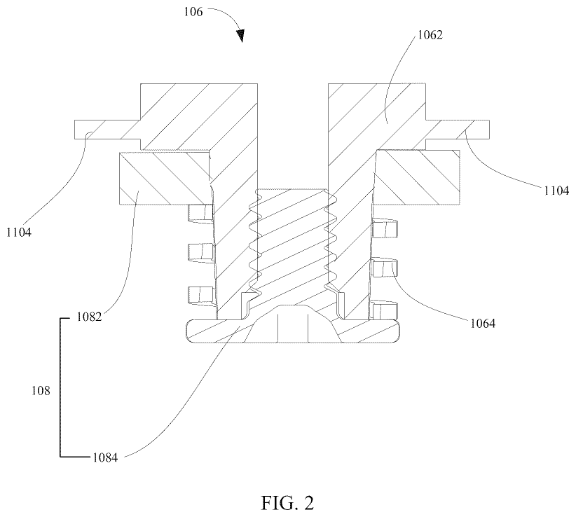

Further, as shown in FIG. 2, the support structure 106 includes: a floating piece 1062, where one end of the floating piece 1062 is rotatably connected to each of the first swing arm 102 and the second swing arm 104; a fixing assembly 108, disposed at another end of the floating piece 1062; and an elastic piece 1064, where the two ends of the elastic piece 1064 contact the fixing assembly 108 and the floating plate respectively; where the elastic piece 1064 has different amounts of deformation when the support structure is in the first position and the second position.

The support structure 106 mainly includes the floating piece 1062, the fixing assembly 108, and the elastic piece 1064. One end of the floating piece 1062 is connected to each of the two swing arms, allowing the floating piece 1062 to move as the two swing arms rotate through mechanical transmission, thereby facilitating the overall posture change of the support structure 106 as the floating piece 1062 moves. At the other end of the floating piece 1062, which is not connected to the two swing arms, there is the fixing assembly 108. The fixing assembly 108 mainly serves to fix the floating piece 1062. It can be understood that the floating piece 1062 moves as the first swing arm 102 and the second swing arm 104 rotate. To ensure that the floating piece 1062 can provide good support for the external screen regardless of its position, the elastic piece 1064 and the fixing assembly 108 are disposed to provide auxiliary support. The two ends of the elastic piece 1064 respectively contact the fixing assembly 108 and the floating piece 1062, mainly utilizing the displacement of the floating piece 1062 occurring when its position changes, for example, when in the first position, and converting the displacement into elastic potential energy. When moving to the second position, the elastic potential energy is released, thereby achieving support for the external screen regardless of the position.

In some embodiments, when the first swing arm 102 and the second swing arm 104 rotate until the support structure is in the first position, the overall posture of the support structure 106 corresponds to the movement of the floating piece 1062 to a first operation position. When the first swing arm 102 and the second swing arm 104 rotate until the support structure is in the second position, the overall posture of the support structure 106 corresponds to the movement of the floating piece 1062 to a second operation position.

It should be noted that when the floating piece 1062 is in the first operation position, the first swing arm 102 and the second swing arm 104 can be in an expanded state. When the floating piece 1062 is in the second operation position, the first swing arm 102 and the second swing arm 104 can be in a contracted state.

Further, the floating piece 1062 has a threaded hole, and the fixing assembly 108 includes: a fixed plate 1082, fitting around the outside of the floating piece 1062; and a floating screw 1084, detachably connected to the floating piece 1062 through the threaded hole, where two ends of the elastic piece 1064 contact the fixed plate 1082 and the floating screw 1084 respectively. Distance between the fixed plate 1082 and the floating screw 1084 when the support structure is in the first position is smaller than distance between the fixed plate 1082 and the floating screw 1084 when the support structure is in the second position.

The fixing assembly 108 mainly includes the fixed plate 1082 and the floating screw 1084. A threaded hole is provided inside the floating piece 1062, allowing the floating screw 1084 to be fixed on the floating piece 1062. On this basis, the two ends of the elastic piece 1064 respectively contact the fixed plate 1082 and the floating screw 1084, allowing the floating piece 1062 in moving to drive the floating screw 1084 to move along with it. Since the position of the fixed plate 1082 is relatively fixed, the floating piece 1062 and the floating screw 1084 will move relative to the fixed plate 1082, compressing or stretching the elastic piece 1064. In some embodiments, when the support structure 106 is in the first position, the distance between the fixed plate 1082 and the floating piece 1062 is larger, and the distance between fixed plate 1082 and the floating screw 1084 is smaller, indicating that the length of the elastic piece 1064 is smaller. This can correspond to the first swing arm 102 and the second swing arm 104 being in an expanded state. When the support structure 106 is in the second position, the length of the elastic piece 1064 is larger, corresponding to the first swing arm 102 and the second swing arm 104 being in a contracted and expanded state.

Further, as shown in FIG. 3, also included are first snap-fit pieces 1102, disposed on the first swing arm 102 and the second swing arm 104; and second snap-fit pieces 1104, disposed at two ends of the support structure 106; where through cooperation of the first snap-fit pieces 1102 and the second snap-fit pieces 1104, the rotation of the first swing arm 102 and the second swing arm 104 drives the support structure 106 to move accordingly.

With the first snap-fit pieces 1102 on the two swing arms and the second snap-fit pieces 1104 at the two ends of the support structure 106, the combined action of the first snap-fit pieces 1102 and the second snap-fit pieces 1104 can link the first swing arm 102 and the support structure 106 and link the second swing arm 104 and the support structure 106, that is, when the first swing arm 102 and the second swing arm 104 rotate, they drive the support structure 106 to move, facilitating the change in posture of the support structure 106.

It can be understood that the first snap-fit pieces 1102 and the second snap-fit pieces 1104 are used to realize the linkage between the swing arms and the support structure 106.

Further, as shown in FIG. 3, also included are limiting pieces 1106, disposed adjacent to the first snap-fit pieces 1102 on the first swing arm 102 and the second swing arm 104. The limiting pieces 1106 are configured to limit the rotation angles of the first swing arm 102 and the second swing arm 104.

With the limiting pieces 1106 on the first swing arm 102 and the second swing arm 104, the rotation ranges of the second snap-fit pieces 1104 can be limited. Since the second snap-fit pieces 1104 are disposed at the two ends of the support structure 106, the activity range of the support structure 106 can be limited under the action of the limiting pieces 1106, preventing excessive movement of the floating piece 1062 from damaging the screen.

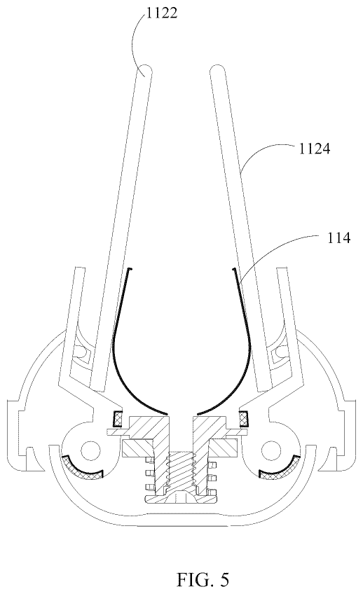

Further, as shown in FIG. 5, also included are a first support plate 1122, disposed on one side of the first swing arm 102, the first support plate 1122 being connected to the first swing arm 102; and a second support plate 1124, disposed on one side of the second swing arm 104, the second support plate 1124 being connected to the second swing arm 104.

With the first support plate 1122 on one side of the first swing arm 102 and the second support plate 1124 on one side of the second swing arm 104, large-area support can be achieved, thereby increasing the support area when a screen is disposed outside the two support plates, improving the support effect.

It should be emphasized that the display screen 206 should be disposed on the outer side of the support plates, that is, on the side of the support plates away from the swing arms.

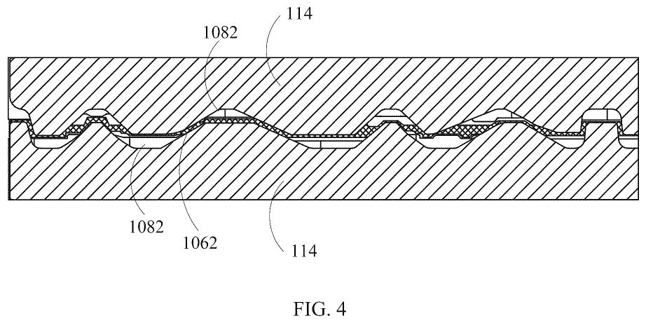

Further, as shown in FIGS. 4 and 5, also included are reinforcement support strips 114, disposed on a side of the first support plate 1122 away from the first swing arm 102 and on a side of the second support plate 1124 away from the second swing arm 104.

With the reinforcement support strips 114 on the first support plate 1122 and the second support plate 1124, the gap between the fixed plate 1082 and the floating piece 1062 can be avoided, preventing the reinforcement support strips 114 from getting caught in the gap between the fixed plate 1082 and the floating plate during rotation. In some embodiments, the reinforcement support strips are disposed on the outer side of the first support plate 1122 and the second support plate 1124, providing a certain level of protection for the external screen.

The reinforcement support strips 114 can be thin steel strips.

Further, each reinforcement support strip 114 is streamlined at an edge facing the other reinforcement support strip 114, and a gap is present between the two reinforcement support strips 114.

With the opposing edges of the reinforcement support strips 114 streamlined, that is, for the two reinforcement support strips 114, the edge of each reinforcement support strip 114 facing the other reinforcement support strip 114 is streamlined, and with a gap defined between the two reinforcement support strips 114, the possibility of interference is reduced when the first swing arm 102 and the second swing arm 104 rotate. Additionally, using a streamlined structure can reduce concentrated stress, increasing the lifespan.

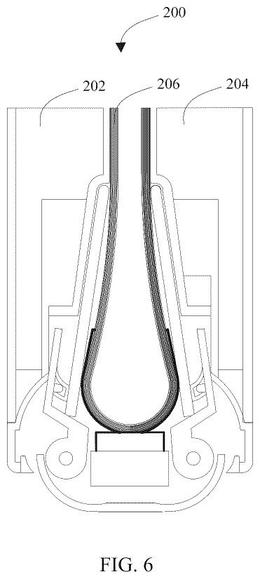

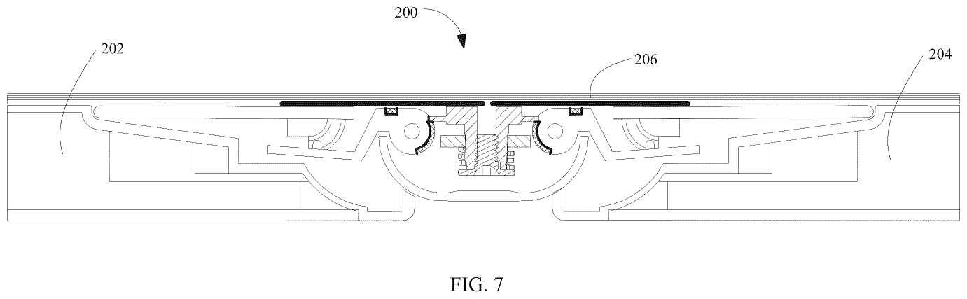

As shown in FIGS. 6 and 7, an embodiment of a second aspect of this application provides a foldable device 200, including: a first folding body 202 and a second folding body 204; and any hinge structure 100 in the embodiments of the first aspect, where the first swing arm 102 of the hinge structure 100 is connected to the first folding body 202, and the second swing arm 104 of the hinge structure 100 is connected to the second folding body 204.

The foldable device 200 provided according to the embodiment of this application mainly includes the first folding body 202, the second folding body 204, and the hinge structure 100. The first folding body 202 and the second folding body 204 are connected to the hinge structure 100, allowing the first folding body 202 and the second folding body 204 to rotate relative to each other, thereby changing the overall posture of the foldable device 200. In some embodiments, the first folding body 202 is connected to the first swing arm 102 of the hinge structure 100, and the second folding body 204 is connected to the second swing arm 104 of the hinge structure 100, so that the rotation of the first swing arm 102 and the second swing arm 104 can drive the first folding body 202 and the second folding body 204 to rotate accordingly.

Furthermore, since the foldable device 200 includes the hinge structure 100 in any one of the embodiments above, it therefore has the effects of any one of the embodiments.

Further, as shown in FIGS. 6 and 7, also included is a display screen 206, disposed on one side of the first folding body 202 and the second folding body 204. When the support structure is in the first position, the display screen 206 is unfolded; and when the support structure is in the second position, the display screen 206 is folded.

With the display screen 206 on one side of the two folding bodies, that is, the display screen 206 being disposed on one side of the first folding body 202 and the second folding body 204, the form of the display screen 206 can change as the first swing arm 102 and the second swing arm 104 rotate to different positions. Further, the display screen 206 can be a flexible screen, or a combination of a flexible screen and a rigid screen. In some embodiments, when the support structure 106 is in the first position, as shown in FIG. 7, the display screen 206 is spread out and unfolded; while when the support structure 106 is in the second position, as shown in FIG. 6, the display screen 206 is folded.

In a specific embodiment, a hinge scheme is provided, including structures such as a fixed middle plate (that is, fixed plate 1082), a floating plate (that is, floating piece 1062), left and right support plates (that is, first support plate 1122 and second support plate 1124), left and right swing arms (that is, first swing arm 102 and second swing arm 104), ultra-thin steel strips (that is, reinforcement support strips 114), a screw (that is, floating screw 1084), and a compression spring (that is, elastic piece 1064). The extra floating plate (the position of the floating plate controlled by the compression spring structure) can prevent the middle support plate from squeezing the foldable screen in the closed state and support the foldable screen in the flat state. At the same time, the ultra-thin steel strips are designed in a streamlined manner, not only to avoid the gap between the floating plate and the fixed middle plate, preventing them from getting caught in the gap during rotation, but also to reduce the internal structural stress of the ultra-thin steel strips, extending their lifespan.

In the flat state, the left and right swing arms lift the floating plate, and the floating plate drives the screw to move up, putting the compression spring in a compressed state. The left and right swing arms support the floating plate, maintaining the position of the floating plate, thereby ensuring the screen does not sink.

In the closed state, the left and right swing arms release the floating plate, and under the rebound force of the compression spring, the floating plate moves downward. Additionally, floating plate limit ribs are designed on the left and right swing arms to prevent the floating plate from squeezing the screen. During mechanical testing, the compression spring acts as a buffer, reducing damage to the screen.

Additionally, the ultra-thin steel strips used for screen protection avoid the gap between the fixed middle plate and the floating plate, preventing the steel strips from getting caught in the gap between the fixed middle plate and the floating plate during rotation. Furthermore, the ultra-thin steel strips are streamlined, which can reduce concentrated stress and increase lifespan.

In the hinge structure and foldable device according to the embodiments of this application, a movable support structure is provided, which can adopt different postures as the first swing arm and the second swing arm rotate to different positions, providing better support for the display screen.

In the description of this specification, the description of the terms such as “an embodiment,” “some embodiments, and “a specific embodiment,” mean that a particular feature, structure, material, or characteristic described in connection with the embodiment or example is included in at least one embodiment or example of this application. In this specification, the schematic representation of the above terms does not necessarily refer to the same embodiment or example. Furthermore, the particular features, structures, materials, or characteristics described may be combined in any suitable manner in one or more embodiments or examples.

The above described are only some embodiments of this application which are not intended to limit this application. For those of ordinary skill in the art, this application may have various modifications and changes. Any modifications, equivalent substitutions, and improvements made within the spirit and principles of this application fall within the protection scope of this application.

What is claimed is:

1. A hinge structure, comprising:
a first swing arm and a second swing arm; and
a support structure, disposed between the first swing arm and the second swing arm, wherein during rotation of the first swing arm and the second swing arm, two ends of the support structure are configured to contact the first swing arm and the second swing arm respectively, enabling the support structure to move between a first position and a second position,
wherein posture of the support structure in the first position is different from posture of the support structure in the second position.

2. The hinge structure according to claim 1, wherein the support structure comprises:
a floating piece, one end of the floating piece being rotatably connected to each of the first swing arm and the second swing arm;
a fixing assembly, disposed at another end of the floating piece; and
an elastic piece, two ends of the elastic piece contacting the fixing assembly and the floating piece respectively,
wherein the elastic piece has different amounts of deformation when the support structure is in the first position and the second position.

3. The hinge structure according to claim 2, wherein the floating piece has a threaded hole, and the fixing assembly comprises:
a fixed plate, fitting around the outside of the floating piece; and
a floating screw, detachably connected to the floating piece through the threaded hole, wherein two ends of the elastic piece contact the fixed plate and the floating screw respectively,
wherein distance between the fixed plate and the floating screw when the support structure is in the first position is smaller than distance between the fixed plate and the floating screw when the support structure is in the second position.

4. The hinge structure according to claim 1, further comprising:
first snap-fit pieces, disposed on the first swing arm and the second swing arm; and
second snap-fit pieces, disposed at two ends of the support structure,
wherein through cooperation of the first snap-fit pieces and the second snap-fit pieces, rotation of the first swing arm and the second swing arm drives the support structure to move accordingly.

5. The hinge structure according to claim 4, further comprising:
limiting pieces, wherein the limiting pieces are disposed adjacent to the first snap-fit pieces on the first swing arm and the second swing arm, and the limiting pieces are configured to limit rotation angles of the first swing arm and the second swing arm.

6. The hinge structure according to claim 2, further comprising:
a first support plate, disposed on one side of the first swing arm, wherein the first support plate is connected to the first swing arm; and
a second support plate, disposed on one side of the second swing arm, wherein the second support plate is connected to the second swing arm.

7. The hinge structure according to claim 6, further comprising:
reinforcement support strips, disposed on a side of the first support plate away from the first swing arm and on a side of the second support plate away from the second swing arm.

8. The hinge structure according to claim 7, wherein each of the reinforcement support strips is streamlined at an edge facing the other one of the reinforcement support strips, and a gap is present between the two reinforcement support strips.

9. A foldable device, comprising: a first folding body, a second folding body, and a hinge structure, wherein the hinge structure comprises:
a first swing arm and a second swing arm; and
a support structure, disposed between the first swing arm and the second swing arm, wherein during rotation of the first swing arm and the second swing arm, two ends of the support structure are configured to contact the first swing arm and the second swing arm respectively, enabling the support structure to move between a first position and a second position,
wherein posture of the support structure in the first position is different from posture of the support structure in the second position;
the first swing arm of the hinge structure is connected to the first folding body; and
the second swing arm of the hinge structure is connected to the second folding body.

10. The foldable device according to claim 9, further comprising:
a display screen, disposed on one side of the first folding body and the second folding body, wherein when the support structure is in the first position, the display screen is unfolded, and when the support structure is in the second position, the display screen is folded.

11. The foldable device according to claim 9, wherein the support structure comprises:
a floating piece, one end of the floating piece being rotatably connected to each of the first swing arm and the second swing arm;
a fixing assembly, disposed at another end of the floating piece; and
an elastic piece, two ends of the elastic piece contacting the fixing assembly and the floating piece respectively,
wherein the elastic piece has different amounts of deformation when the support structure is in the first position and the second position.

12. The foldable device according to claim 11, wherein the floating piece has a threaded hole, and the fixing assembly comprises:
a fixed plate, fitting around the outside of the floating piece; and
a floating screw, detachably connected to the floating piece through the threaded hole, wherein two ends of the elastic piece contact the fixed plate and the floating screw respectively,
wherein distance between the fixed plate and the floating screw when the support structure is in the first position is smaller than distance between the fixed plate and the floating screw when the support structure is in the second position.

13. The foldable device according to claim 9, wherein the hinge structure further comprises:
first snap-fit pieces, disposed on the first swing arm and the second swing arm; and
second snap-fit pieces, disposed at two ends of the support structure,
wherein through cooperation of the first snap-fit pieces and the second snap-fit pieces, rotation of the first swing arm and the second swing arm drives the support structure to move accordingly.

14. The foldable device according to claim 13, wherein the hinge structure further comprises:
limiting pieces, wherein the limiting pieces are disposed adjacent to the first snap-fit pieces on the first swing arm and the second swing arm, and the limiting pieces are configured to limit rotation angles of the first swing arm and the second swing arm.

15. The foldable device according to claim 11, wherein the hinge structure further comprises:
a first support plate, disposed on one side of the first swing arm, wherein the first support plate is connected to the first swing arm; and
a second support plate, disposed on one side of the second swing arm, wherein the second support plate is connected to the second swing arm.

16. The foldable device according to claim 15, wherein the hinge structure further comprises:
reinforcement support strips, disposed on a side of the first support plate away from the first swing arm and on a side of the second support plate away from the second swing arm.

17. The foldable device according to claim 16, wherein each of the reinforcement support strips is streamlined at an edge facing the other one of the reinforcement support strips, and a gap is present between the two reinforcement support strips.
